(19) United States
(12) Patent Application Publication
(10) Pub. No.: US 2015/0170886 A1
(43) Pub. Date: Jun. 18, 2015

(54) PLASMA PROCESSING APPARATUS AND PLASMA PROCESSING METHOD

(71) Applicant: Hitachi High-Technologies Corporation, Tokyo (JP)

(72) Inventors: Michikazu MORIMOTO, Tokyo (JP); Naoki YASUI, Tokyo (JP); Shunsuke KANAZAWA, Tokyo (JP); Yasuo OHGOSHI, Tokyo (JP)

(73) Assignee: Hitachi High-Technologies Corporation

(21) Appl. No.: 14/447,712

(22) Filed: Jul. 31, 2014

(30) Foreign Application Priority Data
Dec. 16, 2013 (JP) 2013-258783

(51) Int. Cl. H01J 37/32; H01L 21/3065; H01L 21/67

(52) U.S. Cl. CPC H01J 37/32935; H01J 37/32128; H01J 37/32165; H01L 21/67069; H01L 21/3065; H01J 2237/327; H01J 2237/334

(57) ABSTRACT

In a plasma processing apparatus having a plasma processing chamber for applying plasma processing to a sample, a first radio frequency power supply for supplying first radio frequency power for generation of a plasma, a sample stage for mounting the sample thereon, a second radio frequency power supply for supplying second radio frequency power to the sample stage, and a pulse-generating unit for sending to the first radio frequency power supply a first pulse for time modulation of the first radio frequency power and for sending to the second radio frequency power supply a second pulse for time modulation of the second radio frequency power, the pulse-generating unit includes a phase control waveform generation unit for generating a phase modulation-use waveform for modulating the phase of ON period of the second pulse and modulates by the phase modulation-use waveform the phase of ON period of the second pulse.

### BACKGROUND OF THE INVENTION

The present invention relates to plasma processing apparatus and plasma processing methodology and, more particularly, to plasma processing apparatus and method suitable for execution of highly accurate etching treatment using a plasma in order to perform plasma processing of samples, such as semiconductor devices or the like.

Prior known methods for processing a surface of semiconductor device include an approach for using an apparatus which uses a plasma to perform etching of the semiconductor device. Prior art will here be explained by taking as an example a plasma etching apparatus of the type employing electron cyclotron resonance (ECR) techniques.

In this ECR technique, a plasma is generated by means of a microwave in a vacuum vessel with a magnetic field being externally applied thereto. Due to the presence of such magnetic field, electrons perform cyclotron motions. By resonating this frequency and the microwave's frequency, it is possible to produce a plasma efficiently. To accelerate ions falling onto a semiconductor device, radio frequency power having a continuous waveform—typically, almost sinusoidal waveform—is applied to the sample. The radio frequency power applied to the sample will be referred to hereinafter as radio frequency bias. The following explanation assumes that the sample is a silicon wafer as one example.

Halogen gases, such as chlorine, fluorine, etc., are widely used for the gas that becomes a plasma. Plasma-created radicals and ions react with a material to be etched whereby the etching progresses. In order to control the etching with an increased accuracy, it is required to perform selection of the radical kind by plasma control and also perform ion content control. Currently available radical/ion control methods include a pulse plasma scheme using a time-modulated plasma. The pulse plasma is the one that controls dissociation by repeating ON and OFF of the plasma to thereby control the dissociation state of radicals and the ion density.

The high-accuracy etching control becomes possible by using specific control parameters including the ON/OFF repetition frequency of a pulse-modulated plasma (referred to hereinafter as pulse frequency), the ratio of ON time to one cycle of the ON/OFF repetition of the pulse-modulated plasma (referred to as duty ratio) and a ratio of ON time to OFF time. For example, a technique for applying a radio frequency bias which is synchronized with a time-modulated microwave while having a constant phase is disclosed in JP-A-02-105413.

### SUMMARY OF THE INVENTION

In the case of applying the radio frequency bias with a continuous waveform to a pulse-modulated plasma, the radio frequency bias is also applied in the OFF time of the pulse-modulated plasma. Generally, the OFF time of the pulse-modulated plasma is low in plasma density; so, the impedance looked at from the radio frequency bias becomes higher, resulting in an increase in the peak-to-peak value (Vpp) of the amplitude of a voltage being applied to a wafer. As the Vpp becomes higher, the ion irradiation energy becomes higher. This can damage the wafer.

As a method of avoiding this damage, there is a method for preventing application of the radio frequency bias within the OFF time of the pulse-modulated plasma. One example is shown in FIG. 1A. It is possible to avoid the wafer damage in OFF time of pulse-modulated plasma by applying time modulation to the radio frequency bias also in a similar way to the pulse-modulated plasma and by repeating ON and OFF in synchronism with the pulse-modulated plasma.

In a pulse-modulated plasma of the ECR system using microwaves, it is a typical way to apply pulse modulation to a microwave used for plasma creation. One exemplary pulse modulation scheme is a method for inputting a pulse signal that becomes the reference to a microwave power supply and for outputting a pulse-modulated microwave by execution of processing inside the power supply. When a plasma is created with the aid of such pulse-modulated microwave, the density of pulse-modulated plasma varies as shown in FIG. 1A.

More specifically, unlike continuous discharge plasma systems, the pulse-modulated plasma density increases upon turn-on of the microwave; however, it takes time until the pulse-modulated plasma density becomes stable.

In the pulse-modulated plasma, a transitional period exists before establishment of the stability of plasma density in every cycle. Similarly, the pulse-modulated plasma's density stability period and OFF time exist in every cycle. Hence, a time period in which the pulse-modulated plasma differs in state exists within one cycle—this is repeated once per every cycle.

Consequently, the inventors as named herein decided to consider the pulse-modulated plasma's one cycle by dividing it into a plurality of time periods based on plasma state characteristics. By division into such plurality of time periods, it becomes possible to take full advantage of the feature of each period. In the example of FIG. 1A, let P1 be the transitional period of ON time, let P2 be a plasma density stability period, and let P3 be the plasma's OFF time. These are repeated on a per-cycle basis. In view of the fact that the plasma density and dissociation state are different in P1, P2 and P3 respectively, effects obtainable for the etching in respective periods are different from one another. Thus, it can be considered that the etching performance differs depending on which one of these periods P1, P2 and P3 is selected for application of the radio frequency bias.

Conventionally, a method is typically used for setting up the ON and OFF times of radio frequency bias by means of the modulation pulse frequency and the duty ratio and for setting up the phase of the pulse-modulated plasma with respect to ON timing by the delay time. In cases where it is wanted to perform etching in any desired period such as P1, P2 or P3, a technique may be employed for adjusting the ON time and OFF time using the radio frequency bias's modulation pulse frequency and duty ratio and for adjusting the timing by the phase. However, this prior art method is incapable of obtaining high-accuracy process control performances because it is merely able to select only one from among P1-P3.

The present invention has been made in view of the technical background stated above, and its object is to provide a plasma processing apparatus and plasma processing method capable of achieving high-accuracy process control in plasma processing apparatus and method of the type applying time modulation to plasma production-use radio frequency power and radio frequency bias power.

In accordance with one aspect of this invention, a plasma processing apparatus is arranged to include a plasma processing chamber which applies plasma processing to a sample, a first radio frequency power supply which supplies first radio frequency power for generation of a plasma in the plasma processing chamber, a sample stage for mounting the sample thereon, a second radio frequency power supply which supplies second radio frequency power to the sample stage, and a pulse-generating unit which sends to the first radio frequency power supply a first pulse for time modulation of the first radio frequency power and sends to the second radio frequency power supply a second pulse for time modulation of the second radio frequency power. In the apparatus, the pulse-generating unit includes a phase control waveform generation unit for generating a phase modulation-use waveform for modulating the phase of ON period of the second pulse and modulates the phase of ON period of the second pulse by the phase modulation-use waveform.

In accordance with another aspect of this invention, a plasma processing apparatus includes a plasma processing chamber which applies plasma processing to a sample, a first radio frequency power supply which supplies first radio frequency power for generation of a plasma in the plasma processing chamber, a sample stage for mounting the sample thereon, a second radio frequency power supply which supplies second radio frequency power to the sample stage, and a pulse-generating unit which sends to the first radio frequency power supply a first pulse for time modulation of the first radio frequency power and sends to the second radio frequency power supply a second pulse for time modulation of the second radio frequency power. In the apparatus, the pulse-generating unit includes a phase control waveform generation unit for generating a phase modulation-use waveform for modulating the phase of ON period of the first pulse and modulates the phase of ON period of the first pulse by the phase modulation-use waveform.

In accordance with a further aspect of this invention, a plasma processing method is provided for performing plasma processing of a sample by using a plasma which is time-modulated by a first pulse while simultaneously supplying the sample with radio frequency power that is time-modulated by a second pulse, wherein the phase of ON period of the second pulse is modulated using the phase modulation-use waveform.

In accordance with this invention, it is possible to perform high-accuracy process control in the plasma processing apparatus and method of the type applying time modulation to the plasma production-use radio frequency power and the radio frequency bias power.

### BRIEF DESCRIPTION OF THE DRAWINGS

FIGS. 1A and 1B are diagrams each showing a relationship of a pulse-modulated plasma and plasma density.

FIGS. 2A and 2B are diagrams showing etching performances in respective time periods of the pulse-modulated plasma.

FIG. 3 is a diagram showing a case where a radio frequency bias is applied in P1 of the pulse-modulated plasma.

FIG. 4 is a diagram showing a case where a radio frequency bias is applied in P2 of the pulse-modulated plasma.

FIG. 5 is a diagram showing, in longitudinal cross-section, a microwave ECR plasma etching apparatus in accordance with one embodiment of this invention.

FIG. 6 is a diagram showing a configuration of a pulse-generating unit.

FIG. 7 is a diagram showing a generation method of a phase-modulated modulation signal of radio frequency bias.

FIG. 8 is a diagram showing a configuration of the pulse-generating unit.

FIG. 9 is a diagram showing a method of generating a phase-modulated modulation signal of radio frequency bias.

FIGS. 10A and 10B are diagrams showing a selection ratio, known as the selectivity, of poly-etch rate with respect to SiO₂ etch rate in each phase pattern of radio frequency bias application.

### DESCRIPTION OF THE EMBODIMENTS

Embodiments of this invention will be described with reference to the accompanying drawings below.

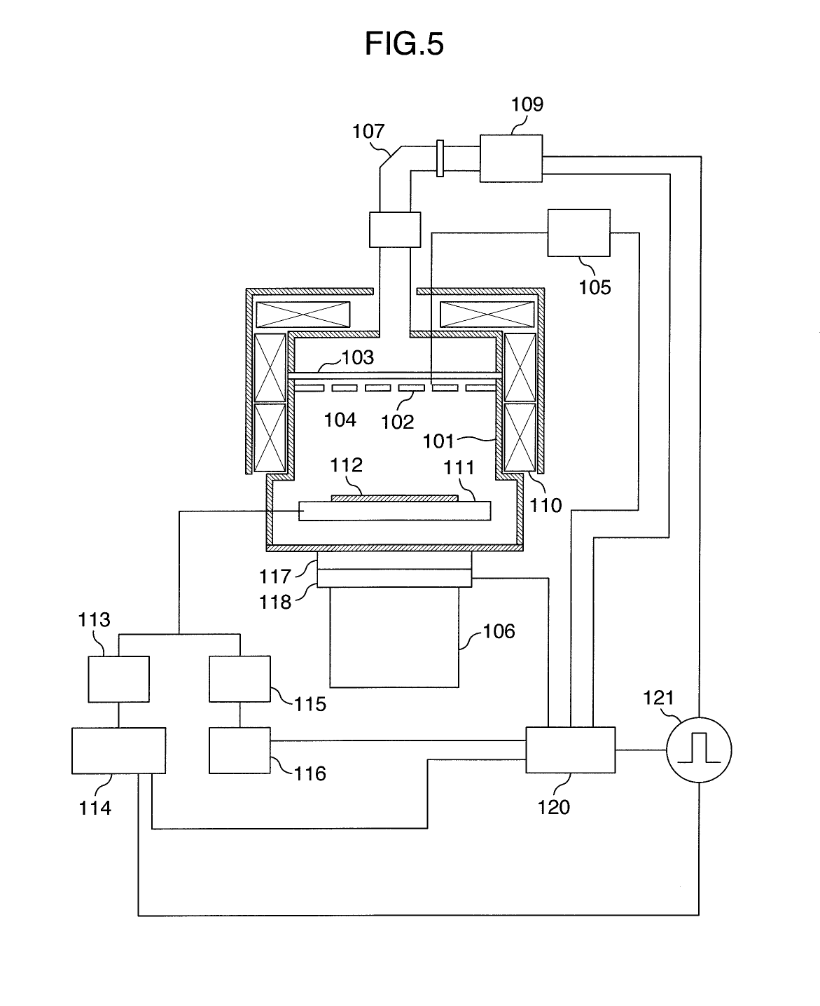

Shown in FIG. 5 is a schematic longitudinal cross-sectional view of a microwave plasma etching apparatus of the type using electron cyclotron resonance (ECR) scheme in accordance with one embodiment of this invention. At upper part of a vacuum vessel 101 with its top being opened, a shower plate 102 (made of quartz, for example) for introducing an etching gas or gases into the vacuum vessel 101 and a dielectric window 103 (e.g., made of quartz) are installed, which are then sealed closely to thereby form a processing chamber 104 that is a plasma processing chamber. Coupled to the shower plate 102 is a gas supply device 105 for flowing an etching gas(es). A vacuum evacuation device 106 is connected to the vacuum vessel 101 through a gas exhaust valve 117 and an exhaust speed-variable valve 118. The processing chamber 104's interior space is depressurized by opening the exhaust valve 117 and by driving the vacuum evacuation device 106 whereby a vacuum is formed therein. An internal pressure of the processing chamber 104 is adjusted to a desired level by means of the exhaust speed-variable valve 118. The etching gas is introduced into processing chamber 104 from gas supply device 105 via shower plate 102, and is exhausted by vacuum evacuation device 106 through exhaust speed-variable valve 118. Additionally, a sample-mounting electrode 111 for use as a sample table or “stage” is provided at under-part of the vacuum vessel 101 in such a manner as to oppose shower plate 102.

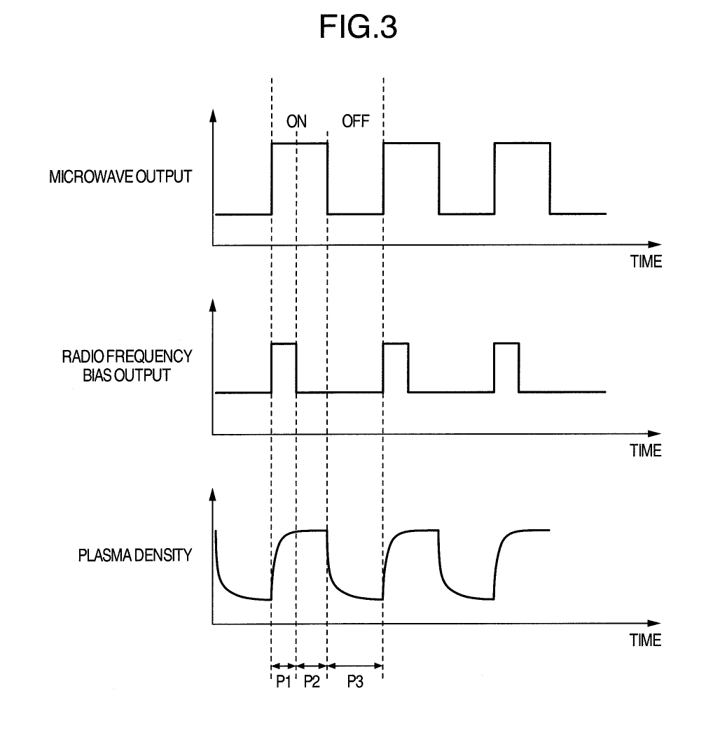

To supply the processing chamber 104 with radio frequency power for plasma generation, a waveguide 107 which transfers an electromagnetic wave is provided above the dielectric window 103. The electromagnetic wave that is transferred to waveguide 107 is oscillated from an electrical power supply 109 for the use of electromagnetic wave generation, which will be called the first radio frequency power supply. A pulse-generating unit 121 is attached to the electromagnetic wave generation power supply 109, thereby making it possible to perform pulse modulation of a microwave at an arbitrarily settable repetition frequency as shown in FIG. 3. In this embodiment, the microwave is 2.45 GHz in frequency although effects of the embodiment are not specifically limited to the electromagnetic wave frequency.

A magnetic field generation coil 110 which creates a magnetic field is provided outside the processing chamber 104. The electromagnetic wave oscillated by the electromagnetic wave generation power supply 109 reacts with the magnetic field created by magnetic field generation coil 110 to thereby produce a high-density plasma in the processing chamber 104, which is used to apply etching treatment to a wafer 112 that is a sample being placed on the sample-mounting electrode 111, i.e., a sample stage. The shower plate 102, sample-mounting electrode 111, magnetic field generation coil 110, exhaust valve 117, exhaust speed-variable valve 118 and wafer 112 are disposed in a coaxial manner with respect to the center axis of processing chamber 104, thus causing the etching gas flow, radicals and ions produced by the plasma and further reaction products created by the etching to be coaxially introduced and exhausted. This coaxial layout has an effect which follows: letting the etching rate and the wafer in-plane uniformity of etching profile come close to the axial symmetry, thus improving the uniformity of wafer processing. Additionally, the sample-mounting electrode 111 has an electrode surface which is covered with a sprayed film (not illustrated), to which is connected a DC power supply 116 via radio frequency filter 115.

Further, a radio frequency bias power supply 114 is connected to the sample-mounting electrode 111 via a matching circuit 113. The radio frequency bias power supply 114 that is the second radio frequency power supply is coupled to pulse-generating unit 121, thereby making it possible to selectively supply sample-mounting electrode 111 with radio frequency power which is time-modulated as shown in FIG. 3. In this embodiment, the radio frequency bias is 400 kHz although effects of the embodiment are not specifically limited to the frequency of radio frequency bias.

A control unit 120 which controls the above-stated ECR microwave plasma etching apparatus is arranged to control, with the aid of an input means (not shown), the repetition frequency including pulse ON/OFF timings of electromagnetic wave generation power supply 109, radio frequency bias power supply 114 and pulse-generating unit 121, duty ratio, and etching parameters for execution of the intended etching, such as gas flow rate, processing pressure, electromagnetic wave power, radio frequency bias power, coil current, pulse ON time and OFF time. Note here that the duty ratio is a ratio of ON time to one cycle of the pulse. In this embodiment, the pulse repetition frequency is changeable within a range of from 5 Hz to 10 kHz whereas the duty ratio is modifiable from 1% to 90%. Setting of the time modulation is enabled for any one of the ON time and OFF time.

Below, the control unit 120 will be described using FIG. 5 in regard to the case of generating a time-modulated electromagnetic wave from the electromagnetic wave generation power supply 109 and the case of supplying time-modulated radio frequency power to sample-mounting electrode 111 from radio frequency bias power supply 114.

The control unit 120 transmits several data to pulse-generating unit 121, the data including the repetition frequency for execution of pulse modulation of electromagnetic wave generation power supply 109 and radio frequency bias power supply 114, duty ratio, and time information combined with the ON timing of electromagnetic wave generation power supply 109 and ON timing of radio frequency bias power supply 114. Time information for pulse output control of the electromagnetic wave generation power supply 109 is sent from pulse-generating unit 121, causing a time-modulated electromagnetic wave to generate from electromagnetic wave generation power supply 109. Similarly, the radio frequency bias power supply 114 generates a time-modulated radio frequency bias output based on the information sent from pulse-generating unit 121.

Information for selecting either synchronization or non-synchronization of the pulse modulation-use waveform of electromagnetic wave generation power supply 109 and the pulse modulation-use waveform of radio frequency bias is also sent from the control unit 120 to pulse-generating unit 121. In this embodiment the pulse modulation-use waveform of electromagnetic wave generation power supply 109 and the pulse modulation-use waveform of radio frequency bias are synchronized with each other. This is done because in the case of non-synchronization, the phase relationship between the pulse modulation-use waveform of electromagnetic wave generation power supply 109 and the pulse modulation-use waveform of radio frequency bias is unable to be kept constant, causing the etching performance control to become difficult.

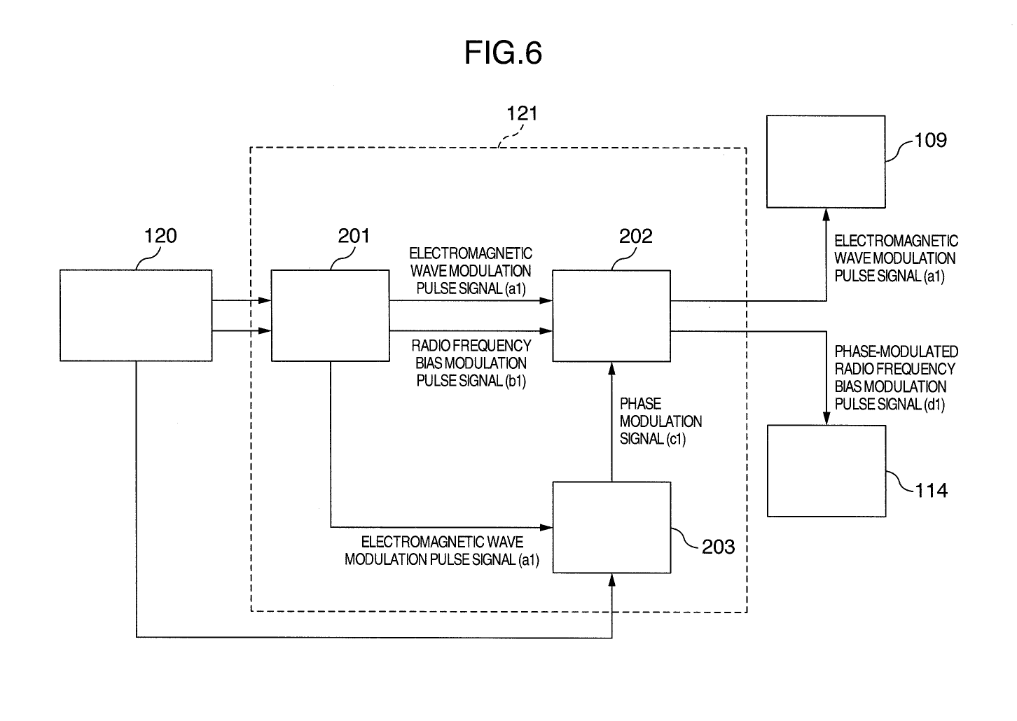

Next, the pulse-generating unit 121 in accordance with an embodiment of this invention will be explained with reference to FIG. 6. The pulse-generating unit 121 includes a pulse generator 201, phase controller 202, and phase control waveform generator 203. A signal having the information as to the pulse modulation repetition frequency and duty ratio for electromagnetic wave generation power supply control is sent from control unit 120 to pulse generator 201. Regarding a control signal for the radio frequency bias power supply use also, a signal having the information as to the pulse modulation repetition frequency and duty ratio is sent from control unit 120 to pulse generator 201. In response to receipt of this signal, the pulse generator 201 generates a pulse waveform for pulse modulation.

The electromagnetic wave modulation pulse signal for control of electromagnetic wave generation power supply 109 is sent from pulse generator 201 to phase controller 202 and phase control waveform generator 203. Inputted to phase control waveform generator 203 are repetition frequencies of the electromagnetic wave modulation pulse signal and phase control-use pulse waveform along with the duty ratio and delay time. Phase control is performed by setting the delay time with the electromagnetic wave modulation pulse signal being as a reference. Hence, the phase control waveform generator 203 acquires the ON timing from the electromagnetic wave modulation pulse signal, thereby generating a phase control signal having a delay time corresponding to the ON timing. By letting phase controller 202 perform computation of the phase control signal and electromagnetic wave modulation pulse signal, it becomes possible to generate the electromagnetic wave modulation pulse signal with its phase varying periodically.

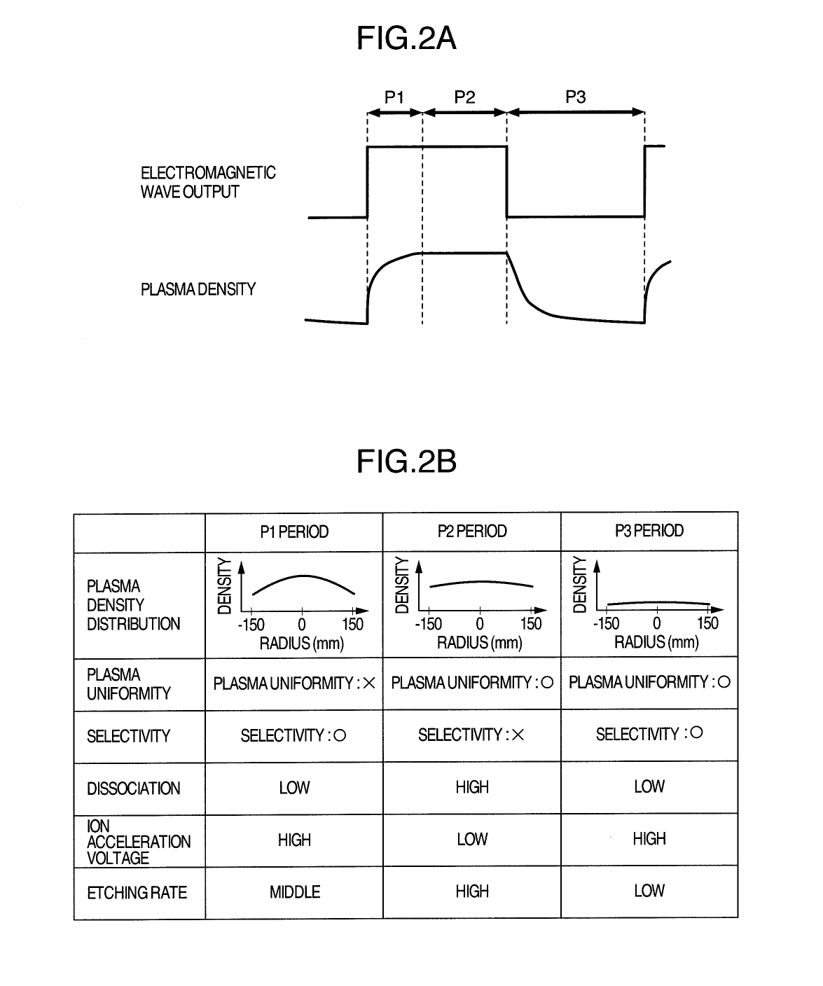

We, the inventors, performed time breakdown measurements about the wafer in-plane distribution of plasma density by Langmuir probe measurement method in order to make sure the behavior of plasma density distribution in ON time period. As a result, it has been revealed that the etching characteristics are different by dividing one cycle of the pulse-modulated plasma into a plurality of time periods as shown in FIGS. 2A and 2B. In P1 time period, the density is high at the central part of the wafer. In P2 period, it has been found that the plasma is in a stable state, resulting in improvement of the uniformity. In P3 period in which the plasma generation is turned off, it has been discovered that the uniformity is further improved. This is unexplainable by the aforementioned model in which the plasma disappears at a wall. It is considered that the plasma disappearance in OFF time of the pulse-modulated plasma is also caused by other factors, such as plasma-and-particle collision, which contribute largely thereto.

From the plasma density measurement result, it is considered that etching is performed within P2 or P3 time period of FIGS. 2A and 2B whereby it becomes possible to increase the uniformity of etching. However, the P2 period is higher in plasma density than P1 and P3 periods; in general, P2 period becomes higher in dissociation than P1 and P3 periods. In a plasma state which is high in dissociation, the etching selectivity becomes lower in a way depending on process conditions and process application. While P3 period is low in dissociation and excellent in uniformity, it is low in plasma density; thus, it is impossible to make the etching rate higher. Although P1 period is not excellent in plasma uniformity, this period is a transitional period of plasma generation and is generally in a low dissociation plasma state; so, the selectivity becomes higher. Briefly, by adequately selecting P1, P2 and P3 period, it is possible to control etching performances with increased accuracy.

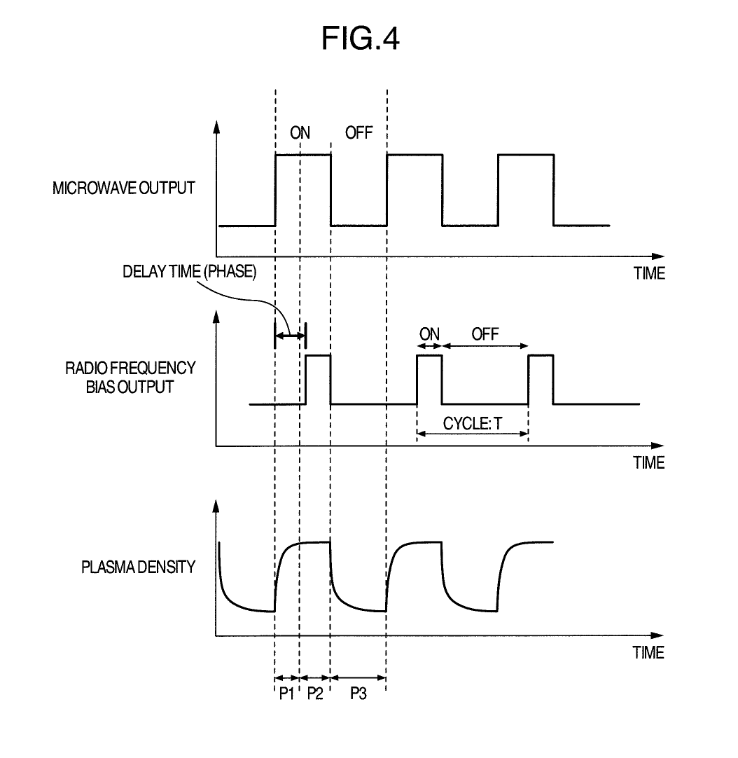

For example, in the case of wanting to perform high-selectivity etching, the application period of the radio frequency bias used to perform ion energy control is set to the P1 period as shown in FIG. 3. Similarly, in the case of wanting to perform uniformity-excellent etching, the radio frequency bias may be applied in P2 period as shown in FIG. 4. As etching progresses mainly within the radio frequency bias applying period, selection of such etching period in P1, P2, P3 is enabled by changing the radio frequency bias application period. To obtain high-accuracy etching control performances, an attempt may be made to perform phase control to thereby control combination of P1, P2, P3 and occurrence frequency. The high-accuracy etching performance control is achievable by providing control as to which one of the time periods is chosen for application of the radio frequency bias to multiple-divided plasma regions at what degree of frequency.

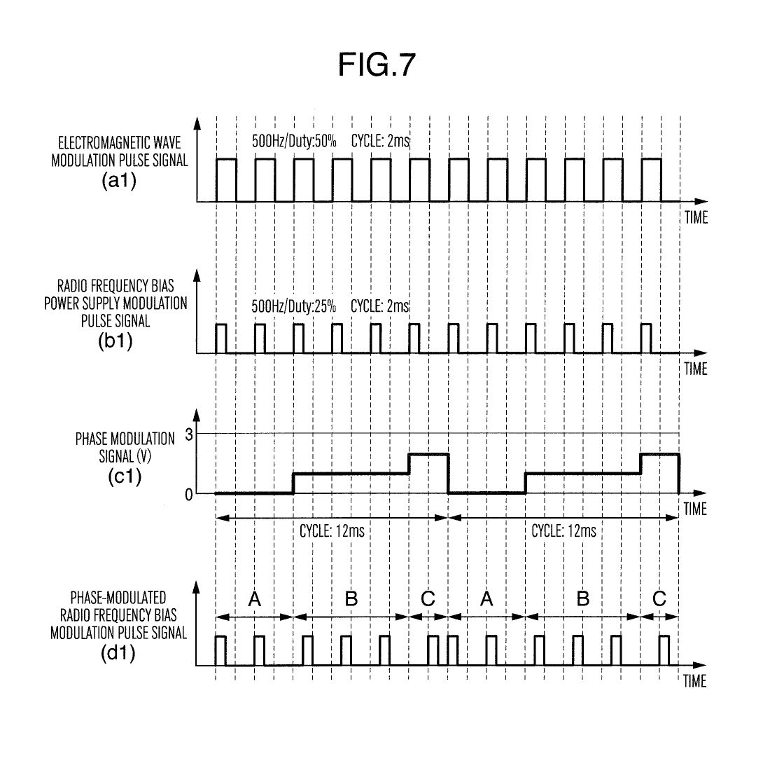

An explanation will next be given, using FIG. 7, of a generation method of the phase modulation-use waveform in this embodiment. In this embodiment, pulses with a repetition frequency of 500 Hz and a duty ratio of 50% were used for the electromagnetic wave modulation. For the radio frequency modulation, pulses with repetition frequency of 500 Hz and duty ratio of 25% were used. To perform etching while selecting the feature per zone of a plasma density change such as shown in FIGS. 2A-2B, the ON time of the radio frequency bias is made shorter than the ON time of electromagnetic wave, thereby facilitating the zone selection.

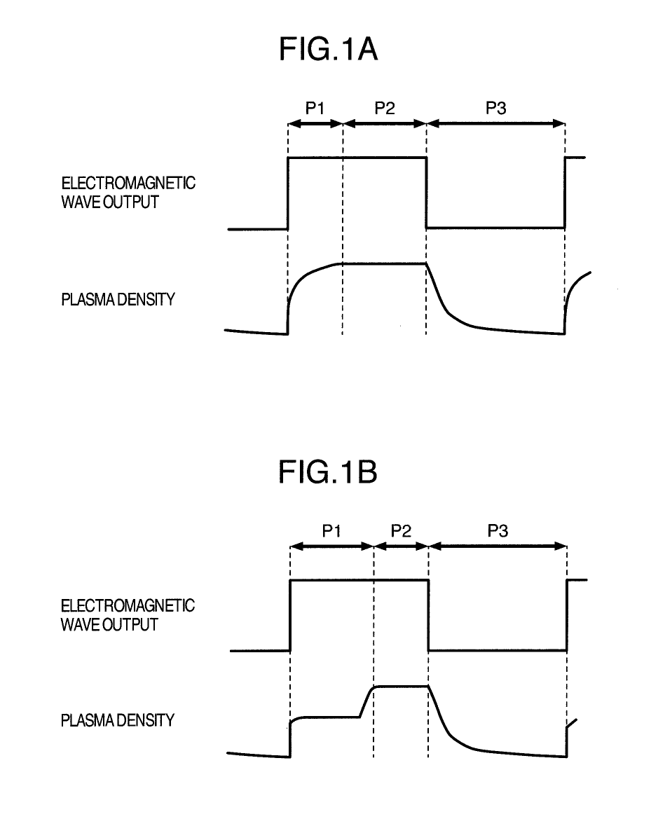

The phase-modulated modulation signal of the radio frequency bias was designed to be a signal having a waveform shown at part (d1) of FIG. 7. This signal is such that the radio frequency bias output has different phases in A, B and C periods respectively in regard to an electromagnetic output. The A period is in the plasma density state of P1 of FIG. 1A; B period is in the plasma density state of P2; C period is in the state of P3. In an example of (d1) of FIG. 7, one cycle is arranged to consist of two P1 periods, three P2 periods and one P3 period.

As process requirements become higher in priority in an order of etching rate uniformity, etching rate and selectivity, the high uniformity-obtainable P2 period was designed so that its number per cycle is greater than the number of P1 periods. While both P1 and P3 are able to attain high selectivity, P3 is low in plasma density, resulting the etch rate goes low excessively. Thus, the number of P1 per cycle is larger than that of P3. As P3 is excellent in high selectivity control, this was decided to be built in the etching.

The phase modulation signal is arranged so that its delay time is controlled by a voltage level. The delay time was set to control at 0.5 ms/V. A phase modulation signal shown at part c1 of FIG. 7 having a potential of 0V in A-period, 1V in B-period, and 2V in C-period is generated at the phase control waveform generator 203. At pulse generator 201, a radio frequency bias modulation pulse signal shown at b1 of FIG. 7 is generated. The radio frequency bias modulation pulse signal of b1 of FIG. 7 and the phase modulation signal of c1 of FIG. 7 are processed at phase controller 202, thereby generating a phase-modulated radio frequency bias modulation pulse signal of d1 of FIG. 7.

In the case of the phase control being performed periodically, the cycle of the phase modulation signal is required to be N times greater than the cycle of electromagnetic wave modulation pulse signal or radio frequency bias modulation pulse signal, where N is a natural number. The cycle in this embodiment was set to 12 ms. This is because of controlling process performances accurately by repeating while letting one set consist of two P1s, three P2s and one P3 in the aforementioned manner. This N-time setup is not needed in cases where a given delay time is used without specifically determining the phase.

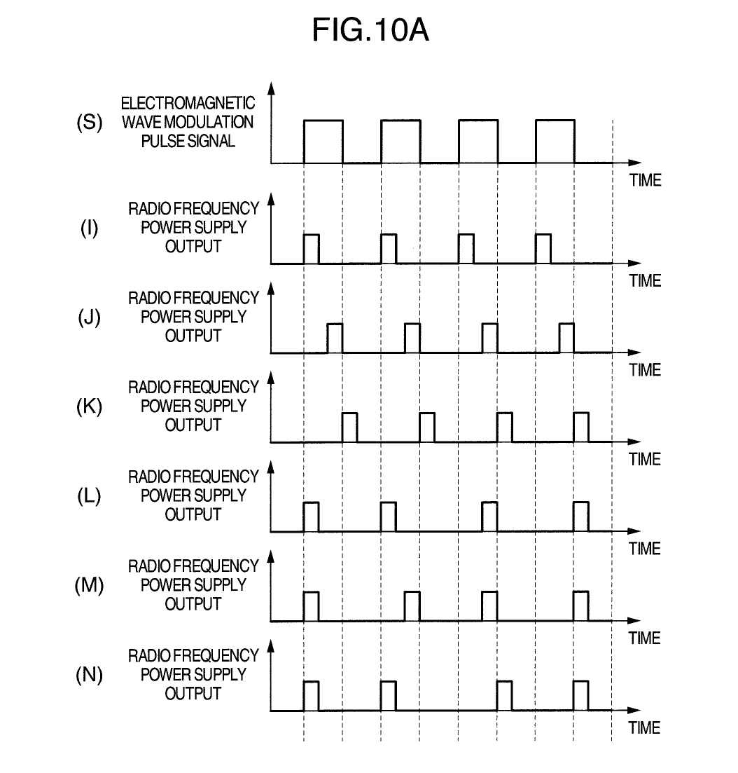

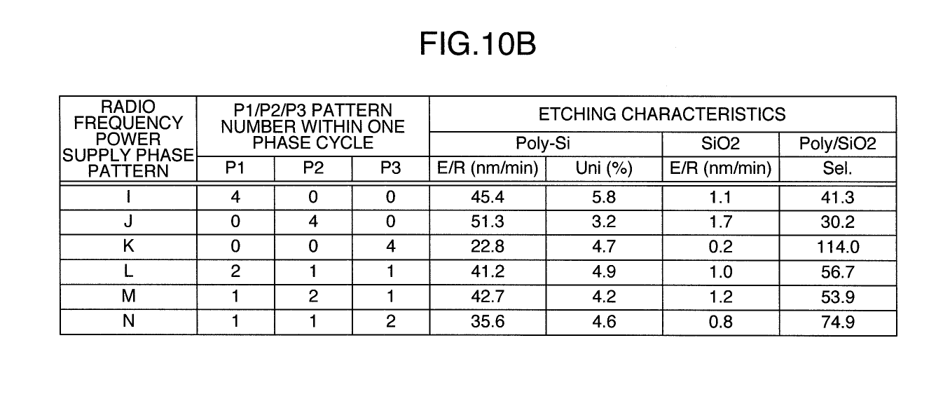

The etching performances achievable by this embodiment will be explained with reference to FIGS. 10A and 10B. Part (S) of FIG. 10A shows an electromagnetic wave modulation pulse output; (I) to (N) are time-modulated radio frequency power supply outputs. Parts (I), (J), (K) of FIG. 10B show etching performance evaluation results; (L), (M), (N) are etching performances calculated from a phase pattern(s) and the etching results of (I), (J), (K). For the etching performance evaluation, a “blanket” wafer with a multilayer structure of a polycrystalline silicon (poly-Si) film and SiO₂ film was used. The frequency of electromagnetic wave output modulation pulse and that of radio frequency bias modulation pulse were set to 1kHz; the duty ratios of the electromagnetic wave output modulation pulse and radio frequency bias modulation pulse were set at 20%.

(I) of FIG. 10B is equivalent to the one that applies the radio frequency bias in P1 shown in FIG. 2A; (J) is equivalent to the one applies the radio frequency bias in P2 of FIG. 2A; (K) is equivalent to the one that applies the radio frequency bias in P3 of FIG. 2A. Although (I), (J), (K) are phase patterns that are realizable by prior art schemes, (L), (M), (N) are not achievable by prior art methods. The above-stated etching conditions are aimed at formation of poly-Si gates. In poly-Si gate fabrication etching, the poly-Si rate, selectivity with the SiO₂ gate film and wafer inplane uniformity are important etching performances.

For example, in cases where requirement values against etching performances are such that the selectivity of poly-Si rate with respect to SiO₂ is more than or equal to 50 and the etching rate uniformity is less than or equal to 5%, the etching rate uniformity and the selectivity of poly-Si rate to SiO₂ are difficult as shown at (I), (J), (K) of FIG. 10B; thus, these values are not satisfiable by prior art methods. On the other hand, use of this invention enables settings of the selectivity of poly-Si rate to SiO₂ at 50 or greater and setting of the etching rate uniformity at 5% or less as in (L), (M), (N) of FIG. 10A; thus, it becomes possible to achieve both the selectivity and the etching rate uniformity at a time. By controlling phase patterns in this way, it is possible to improve the etching performance controllability when compared to prior art methods.

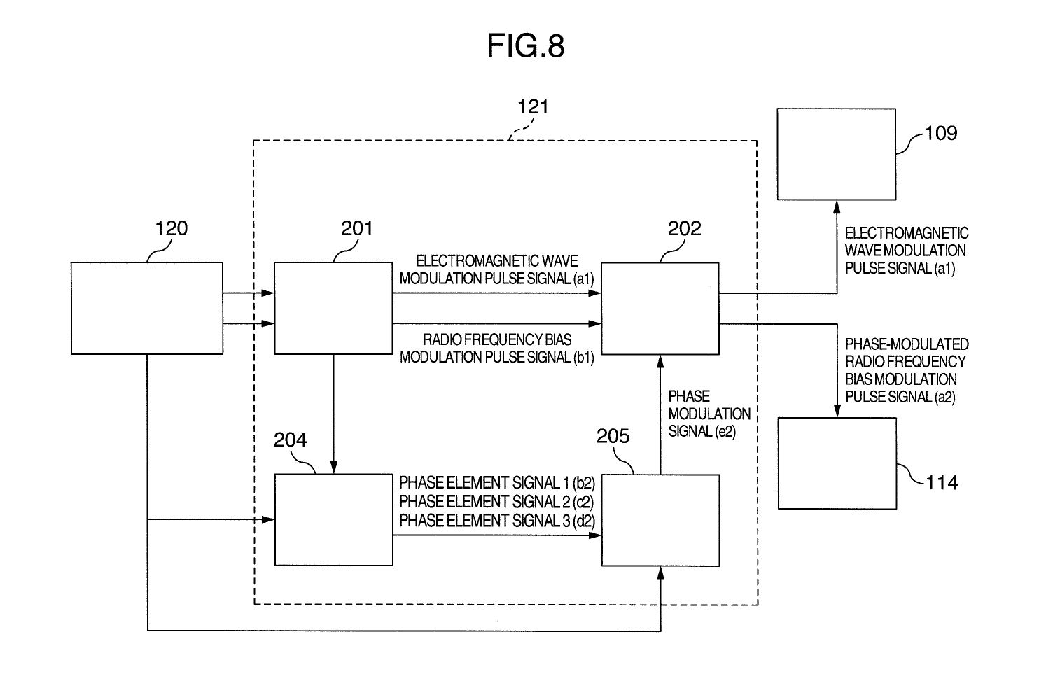

Next, a technique for combining a plurality of phase modulation-use waveforms using the apparatus configuration of FIG. 5 will be explained. Firstly, the pulse-generating unit 121 for combination of a plurality of phase modulations will be described with reference to FIG. 8. A signal having information as to the repetition frequency and duty ratio of modulation pulses for electromagnetic wave-generating power supply control is transmitted from the control unit 120 to pulse generator 201. Regarding the control signal used for radio frequency bias power supply also, a signal having information as to the repetition frequency and duty ratio of modulation pulses is sent from control unit 120 to pulse generator 201 in a similar way. In responding thereto, pulse generator 201 generates a pulse waveform for pulse modulation.

The electromagnetic wave modulation pulse signal for control of electromagnetic wave generation power supply 109 is sent from the pulse generator to phase controller 202 and phase element control waveform generator 204. From control unit 120 to phase element control waveform generator 204, repetition frequencies of the electromagnetic wave modulation pulse signal and the phase element control-use pulse waveform along with their duty ratios and delay times are input.

Phase modulation is performed by setting a delay time with the electromagnetic wave modulation pulse signal being as a reference. Hence, the ON timing is acquired from the electromagnetic wave modulation pulse signal, thereby generating a phase element control signal having the delay time corresponding to the ON timing. By generating a plurality of phase element signals and combining them together, it is possible to perform high-accuracy phase modulation.

The plurality of phase element signals generated by the phase element control waveform generator 204 are able to have different cycles and different duty ratios respectively. These phase element signals generated by phase element control waveform generator 204 are sent to a synthetic phase control waveform generator 205. The synthetic phase control waveform generator 205 synthesizes respective phase element signals and sends a synthesized phase signal to phase controller 202. The phase modulation signal and radio frequency modulation pulse signal are processed by phase controller 202, thereby making it possible to generate the intended radio frequency modulation pulse signal with its phase varying periodically.

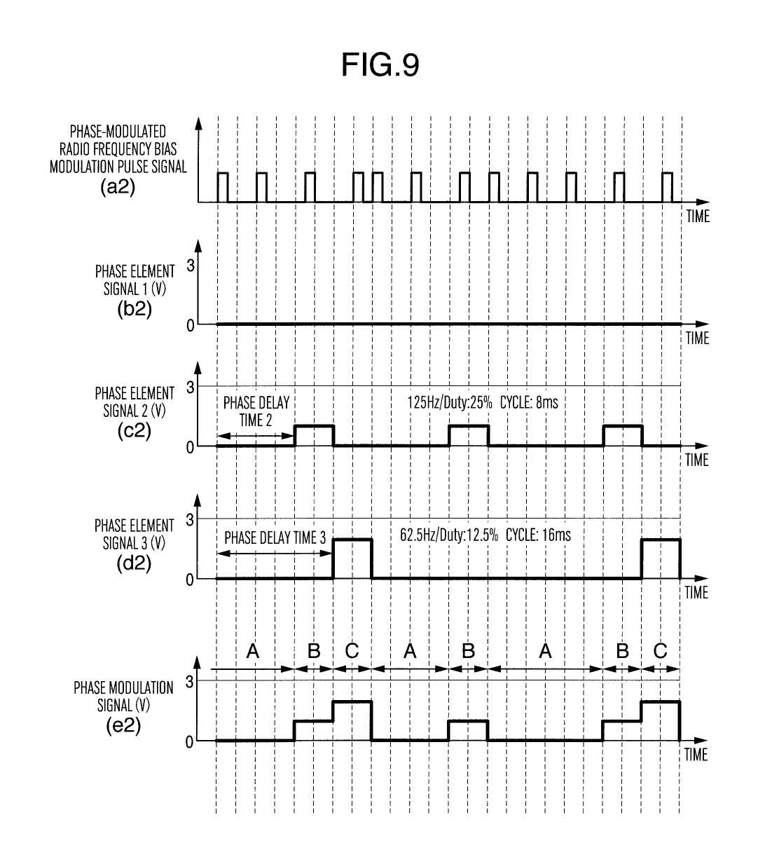

Next, a generating method of the synthetic phase modulation-use waveform in this embodiment will be explained using FIG. 9. In this embodiment, the repetition frequency for electromagnetic wave modulation was set to 500 Hz, and the duty ratio of 50% was used. For radio frequency bias modulation, the repetition frequency is set to 500 Hz and the duty ratio was set at 25%. In order to obtain a radio frequency bias modulation pulse signal shown at part (a2) in FIG. 9, it is necessary to send to the phase controller 202 a synthetic phase modulation signal shown at (e2) in FIG. 9. To generate the synthetic phase modulation signal shown at (e2) of FIG. 9, the phase element control waveform generator 204 generates three kinds of waveforms shown at (b2), (c2), (d2) in FIG. 9. Although in this embodiment the phase elements are set to three, this phase element number may be set to other numbers.

The phase element control signal is such that its delay time is controlled by a voltage level. This delay time was set to control at 0.5 ms/V. The radio frequency bias modulation pulse signal has its waveform substantially consisting of three phases A, B and C. A is a time period in which the delay time is set to 0 ms. B is a period in which the delay time is 0.5 ms. C is a period with the delay time being set to 1 ms. To realize the delay time of A, a phase element signal 1 shown at (b2) in FIG. 9 is generated. Regarding B, the waveform of a phase element signal 2 shown at c2 of FIG. 9 is used. The control unit 120 sends the phase delay time, repetition frequency and duty ratio with respect to each phase element to phase element control waveform generator 204, thereby enabling generation of the phase element signal. In this embodiment, the delay time of phase element signal 2 was set to 4 ms; the repetition frequency was set to 125 Hz; the duty ratio was set at 25%; the period was set at 8 ms.

To vary the phase periodically, the cycle of each phase element needs to be determined so that it is X times greater than the cycle of the electromagnetic wave modulation pulse signal and/or radio frequency bias modulation pulse signal, where X is an integral number. Regarding C, control is done by a phase element signal 3. The phase element signal 3 was designed to have its repetition frequency of 62.5 Hz, duty ratio of 12.5%, and cycle of 16 ms.

By synthesis composition of these three waveforms shown at (b2), (c2) and (d2) of FIG. 9 by the synthetic phase control waveform generator 205, it is possible to generate the synthetic phase modulation signal shown at (b2) of FIG. 9. By synthesis of the synthetic phase modulation signal of (d2) of FIG. 9 and the radio frequency bias modulation pulse signal, it is possible to obtain the radio frequency modulation pulse signal shown at (a2) in FIG. 9.

As has been stated above, by this invention, it becomes possible to obtain a plurality of plasma characteristics rather than a single plasma characteristic by dividing the plasma generation period and then applying a phase pattern control-executed radio frequency bias with respect to divided time periods. This makes it possible to achieve high-accuracy control of process performances.

Although in the above-stated embodiment the explanation was given with the microwave ECR plasma as one embodiment, similar effects and advantages are also obtainable in other types of plasma processing apparatus using a capacitively coupled plasma production scheme, inductively coupled plasma production scheme, etc. A behavior example of the pulse plasma density in a capacitive-coupled plasma apparatus is shown in FIG. 1B.

In the case of generating the pulse modulation plasma by an inductive-coupled plasma apparatus, it will sometimes happen that a mixture of E and H modes is present in the ON time period. In FIG. 1B, P1 is E mode period and P2 is H mode period. E mode is a discharge state similar to the capacitive-coupled plasma; H mode is a discharge state of inductive-coupled plasma. P3 becomes an OFF period. As is well known, in the capacitive- and inductive-coupled plasma states, the plasma density and electron temperature are different—etching performance is also different. Consequently, in the inductive-coupled plasma apparatus also, it is possible by performing the above-stated phase control of this embodiment to achieve high- accuracy etching performance control.

Although in the above-stated embodiment the radio frequency bias phase control is used while dividing the plasma density region into P1, P2 and P3, such plasma region division is not always necessary. With a scheme for controlling the phase of a plasma generation output while dividing the radio frequency bias into a plurality of regions also, it is possible to obtain effects similar to those of this embodiment.

While in the above-stated illustrative embodiment the repetition frequency of electromagnetic wave modulation pulse and the repetition frequency of radio frequency bias modulation pulse are set equal to each other, similar effects are also obtainable with the use of different frequencies. Although the above-stated embodiment is specifically drawn to etching apparatus, this invention may also be applied to plasma processing other than the etching treatment as far as an apparatus used therefor is the one that employs pulse modulation schemes.

In summary, the present invention can be said to be a plasma processing apparatus having a plasma processing chamber which applies plasma processing to a sample, a first radio frequency power supply which supplies first radio frequency power for generation of a plasma in the plasma processing chamber, a sample stage for mounting the sample thereon, a second radio frequency power supply which supplies second radio frequency power to the sample stage, and a pulse-generating unit which sends to the first radio frequency power supply a first pulse for time modulation of the first radio frequency power and sends to the second radio frequency power supply a second pulse for time modulation of the second radio frequency power, characterized in that the pulse-generating unit includes a phase control waveform generation unit for generating a phase modulation-use waveform for modulating the phase of ON period of the second pulse and modulates the phase of ON period of the second pulse by the phase modulation-use waveform.

In addition, the present invention can be said to be a plasma processing apparatus having a plasma processing chamber which applies plasma processing to a sample, a first radio frequency power supply which supplies first radio frequency power for generation of a plasma in the plasma processing chamber, a sample stage for mounting the sample thereon, a second radio frequency power supply which supplies second radio frequency power to the sample stage, and a pulse-generating unit which sends to the first radio frequency power supply a first pulse for time modulation of the first radio frequency power and sends to the second radio frequency power supply a second pulse for time modulation of the second radio frequency power, wherein the pulse-generating unit includes a phase control waveform generation unit for generating a phase modulation-use waveform for modulating the phase of ON period of the first pulse and modulates the phase of ON period of the first pulse by the phase modulation-use waveform.

By these inventive concepts, it becomes possible to control a combination of an optimal plasma state and radio frequency bias, thereby enabling achievement of high-accuracy process control.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising;
a plasma processing chamber for applying plasma processing to a sample;
a first radio frequency power supply for supplying first radio frequency power for generation of a plasma in said plasma processing chamber;
a sample stage for mounting the sample thereon;
a second radio frequency power supply for supplying second radio frequency power to said sample stage; and
a pulse-generating unit for sending to said first radio frequency power supply a first pulse for time modulation of the first radio frequency power and for sending to said second radio frequency power supply a second pulse for time modulation of the second radio frequency power, wherein
said pulse-generating unit comprises a phase control waveform generation unit for generating a phase modulation-use waveform for modulating a phase of ON period of the second pulse and modulates by the phase modulation-use waveform the phase of ON period of said second pulse.

2. The plasma processing apparatus according to claim 1, wherein said phase modulation-use waveform is a signal waveform having a number of different amplitude values, the number corresponding to a number of dividing one cycle of the first pulse into a plurality of time periods.

3. The plasma processing apparatus according to claim 2, wherein the cycle of said phase modulation-use waveform is N times of the cycle of said first pulse, where N is a natural number.

4. The plasma processing apparatus according to claim 2, wherein the ON period of said second pulse is shorter than the first pulse period.

5. A plasma processing apparatus comprising;
a plasma processing chamber for applying plasma processing to a sample;
a first radio frequency power supply for supplying first radio frequency power for generation of a plasma in said plasma processing chamber;
a sample stage for mounting the sample thereon, a second radio frequency power supply for supplying second radio frequency power to said sample stage; and
a pulse-generating unit for sending to said first radio frequency power supply a first pulse for time modulation of the first radio frequency power and for sending to said second radio frequency power supply a second pulse for time modulation of the second radio frequency power, wherein
said pulse-generating unit comprises a phase control waveform generation unit for generating a phase modulation-use waveform for modulating a phase of ON period of the first pulse and modulates by the phase modulation-use waveform the phase of ON period of said first pulse.

6. The plasma processing apparatus according to claim 5, wherein said phase modulation-use waveform is a signal waveform having a number of different amplitude values, the number corresponding to a number of dividing one cycle of the second pulse into a plurality of time periods,

7. The plasma processing apparatus according to claim 6, wherein the cycle of said phase modulation-use waveform is N times of the cycle of said second pulse, where N is a natural number.

8. A plasma processing method for performing plasma processing of a sample by using a plasma being time-modulated by a first pulse while simultaneously supplying the sample with radio frequency power being time-modulated by a second pulse, wherein
a phase of ON period of the second pulse is modulated using a phase modulation-use waveform.

9. The plasma processing method according to claim 8, wherein the phase modulation-use waveform is a signal waveform having a number of different amplitude values, the number corresponding to a number of dividing one cycle of the first pulse into a plurality of time periods.

10. The plasma processing method according to claim 9, wherein the cycle of said phase modulation-use waveform is N times of the cycle of said first pulse, where N is a natural number.

11. The plasma processing method according to claim 9, wherein the ON period of said second pulse is shorter than the first pulse period.
